(19) United States
(12) Patent Application Publication
(10) Pub. No.: US 2026/0371932 A1
(43) Pub. Date: Nov. 19, 2026

(54) CHARGE LEAKAGE COMPENSATION IN PIEZO-ELECTRIC TRANSDUCER CIRCUITS

(71) Applicant: Boréas Technologies Inc., Bromont (CA)

(72) Inventors: Simon Chaput, Bromont (CA); Francis Lacasse, Bromont (CA)

(21) Appl. No.: 19/132,440

(22) PCT Filed: Nov. 17, 2023
(86) PCT No.: PCT/CA2023/051563

§ 371 Date: May 23, 2025

Related U.S. Application Data
(60) Provisional application No. 63/384,987, filed on Nov. 25, 2022.

(51) Int. Cl. H03K 17/14; G06F 3/01; G06F 3/041; H03K 17/13; H10N 30/80

(52) U.S. Cl. CPC H03K 17/145; G06F 3/016; G06F 3/04164; G06F 3/04184; H03K 17/133; H10N 30/802; G06F 2203/04105; H03K 2217/0027

(57) ABSTRACT

In a driver for a piezo-electric transducer, when a converter circuit and a sensing circuit are the same circuit, many limitations exist on the accuracy of the sensing, due to multiple parasitic effects arising from the interconnection of the power devices. These limitations may limit viability of the sensing for many applications, in particular an accurate determination of when the force on the piezo-electric transducer is fully removed. The system self-characterizes the piezo-electric transducer charge leakage in a given system and applies a correction so that the data read represents the real electrical signal corresponding to a force application.

### TECHNICAL FIELD

The present invention relates to piezo-electric transducer circuits, and in particular to a system for compensating for charge leakage in piezo-electric transducer circuits.

### BACKGROUND

In conventional haptic feedback systems, which use the piezo-electric effect, a driver circuit applies a high-voltage signal to the piezo-electric transducer, and in response to the applied high-voltage signal, the piezo-electric transducer generates a mechanical movement sufficient to give a haptic sensation to a user. In addition, when a force is applied to the piezo-electric transducer by the user, a sensing circuit generates a sensed voltage signal, which enables the piezo-electric transducer to act as a switch.

When the driver circuit and the sensing circuit are the same circuit, many limitations exist on the accuracy of the sensing, due to multiple parasitic effects arising from the interconnection of the power devices. These limitations may limit viability of the sensing for many applications.

Piezo-electric transducers typically respond well with AC signals, i.e. as long as the force applied varies somewhat rapidly, the signal is quite accurate and represents the amount of force or mechanical stress the piezo-electric transducers is experiencing. However, piezo-electric transducers may not respond as well for DC signals or other slowly changing signals. The reason is that in any system, there is some level of charge leakage. When the piezo-electric transducer generates or absorbs charges, this typically changes the voltage at the piezo-electric transducer terminals. However, the difference of voltage existing between the terminals of the piezo-electric transducers will decrease with time as electric charges leak through various parasitic paths in the system. This behaviour is problematic because, in a system that uses piezo-electric transducers to estimate the force applied on a surface, the leakage has an impact on the force read based on how fast the force is applied. For instance, in a trackpad, while the typical trigger point could be 150 gf (gram-force), if the force is applied slowly, it is possible the system trigger only at 200 gf due to charge leakage.

An object of the present invention is to overcome the shortcomings of the prior art by providing a more reliable sensing driver circuit for any electro-active transducer, such as a piezo-electric transducer.

### SUMMARY OF THE INVENTION

Accordingly, the present invention relates to a method of operating a piezo-electric driver circuit, the method comprising:
obtaining a leakage characteristic of the piezo-electric driver circuit;
repeatedly sensing a first sensed voltage generated by a first force applied to a first piezo-electric transducer;
zeroing the first sensed voltage each time the first sensed voltage reaches a threshold voltage, thereby generating a plurality of first voltage segments;
generating a digital representation of each of the plurality of first voltage segments;
generating adjusted digital representations based on the leakage characteristic;
updating a first accumulation sum with each adjusted digital representation; and
determining the first total sensed voltage across the first piezo-electric transducer from the first accumulation sum.

According to any of the aforementioned embodiments, the threshold voltage may be based on a first trigger level of a first parasitic conduction path of a first switch in the piezo-electric driver circuit.

According to any of the aforementioned embodiments, the leakage characteristic may comprise an amount of leakage voltage over time.

According to any of the aforementioned embodiments, determining the first total sensed voltage may further include: generating an interim digital representation of each first sensed voltage, each time the first sensed voltage is sensed; adjusting the interim digital representation of each first sensed voltage based on the leakage characteristic; and determining the first total sensed voltage across the first piezo-electric transducer from the first accumulation sum and the interim digital representation.

According to any of the aforementioned embodiments, the first switch in the piezo-electric driver circuit may comprises a driver circuit switch including the first parasitic conduction path, wherein the method comprises transmitting a driver voltage signal to the first piezo-electric transducer for generating a force or displacement response on the first piezo-electric transducer.

According to any of the aforementioned embodiments, the method may further comprise: generating an interim digital representation of each first sensed voltage, each time the first sensed voltage is sensed; and wherein the step of transmitting the driver voltage signal includes transmitting the driver voltage signal when the first total-sensed voltage plus the interim digital representation is greater than a predetermined activation level.

According to any of the aforementioned embodiments, the first threshold voltage may be greater than a negative first turn-on voltage of the first parasitic conduction path.

According to any of the aforementioned embodiments, the first threshold voltage may be less than a positive first turn-on voltage of the first parasitic conduction path.

The disclosure may also relate to an apparatus for operating a first piezo-electric transducer, configured for coupling to a voltage source, which provides an input voltage, and configured to transmit a driver voltage signal across the first piezo-electric transducer, the apparatus comprising:
a driver circuit, comprising a first driver circuit switch including a first parasitic conduction path, configured to be connected to the first piezo-electric transducer, the driver circuit configured to receive the input voltage and transmit the driver voltage signal for generating a force response or a displacement response on the first piezo-electric transducer;
a sensing circuit configured to sense a first sensed voltage generated by a first force applied to the first piezo-electric transducer, the sensing circuit including a first sensing switch; and
a controller configured to: control the first driver switch and the first sensing switch, obtain a leakage characteristic of the driver circuit; repeatedly sense the first sensed voltage generated by the first force applied to a first piezo-electric transducer; zero the first sensed voltage each time the first sensed voltage reaches a threshold voltage, thereby generating a plurality of first voltage segments; generate a digital representation of each of the plurality of first voltage segments; generate adjusted digital representations based on the leakage characteristic; update a first accumulation sum with the adjusted digital representations; and determine a first total sensed voltage across the first piezo-electric transducer from the first accumulation sum.

According to any of the aforementioned embodiments, the threshold voltage may be based on a first trigger level of the first parasitic conduction path.

According to any of the aforementioned embodiments, the controller may also configured to: generate an interim digital representation of the first sensed voltage, each time the first sensed voltage is sensed; adjust the interim digital representation of one or more of the first sensed voltage based on the leakage characteristic; and determine the first total sensed voltage across the first piezo-electric transducer from the first accumulation sum and the interim digital representation.

According to any of the aforementioned embodiments, the controller may also be configured to: generate an interim digital representation of the first sensed voltage, each time the first sensed voltage is sensed; adjust the interim digital representation of each of the first sensed voltage based on the leakage characteristic; and determine the first total sensed voltage across the first piezo-electric transducer from the first accumulation sum and the interim digital representation.

According to any of the aforementioned embodiments, the controller may also be configured to: generate an interim digital representation of the first sensed voltage, each time the first sensed voltage is sensed; adjust the interim digital representation of one or more of the first sensed voltage based on the leakage characteristic; and transmit the driver voltage signal when the first total sensed voltage, comprising the first accumulation sum plus the interim digital representation, is greater than a predetermined activation level.

According to any of the aforementioned embodiments, the threshold voltage may be greater than a negative turn-on voltage of the first parasitic conduction path.

Accordingly the present invention may also relate to a method of operating a piezo-electric transducer with a piezo-electric driver circuit, including a first switch with a first parasitic conduction path, the method comprising:
determining a charge leakage characteristic of the piezo-electric driver circuit;
repeatedly sensing a first sensed voltage generated by a first force applied to the piezo-electric transducer;
generating a digital representation of the first sensed voltage;
generating an adjusted digital representation of the first sensed voltage based on the leakage characteristic; and
transmitting a driver voltage signal to the first piezo-electric transducer for generating a force response or a displacement response on the first piezo-electric transducer when the adjusted digital representation of the first sensed voltage reaches a target force threshold voltage.

According to any of the aforementioned embodiments, the threshold voltage may be based on a first trigger level of the first parasitic conduction path.

According to any of the aforementioned embodiments, the leakage characteristic may comprises an amount of leakage voltage over time.

The disclosure also relates to an apparatus for operating a first piezo-electric transducer, configured for coupling to a voltage source, which provides an input voltage, and configured to transmit a drive voltage across the first piezo-electric transducer, the apparatus comprising:
a driver circuit, comprising a first driver circuit switch including a first parasitic conduction path, configured to be connected to the first piezo-electric transducer, the driver circuit configured to receive the input voltage and transmit the drive voltage for generating a force or displacement response on the first piezo-electric transducer;
a sensing circuit configured to sense a first sensed voltage generated by a first force applied to the first piezo-electric transducer, the sensing circuit including a first sensing switch; and
a controller configured for: determining a charge leakage characteristic of the driver circuit; repeatedly sensing the first sensed voltage generated by the first force applied to the piezo-electric transducer; generating a digital representation of the first sensed voltage; generating an adjusted digital representation of the first sensed voltage based on the leakage characteristic; and transmitting a drive voltage to the first piezo-electric transducer for generating a force response or displacement response on the first piezo-electric transducer when the adjusted digital representation of the first sensed voltage reaches a target force threshold voltage.

According to any of the aforementioned embodiments, threshold voltage may be based on a first trigger level of the first parasitic conduction path.

According to any of the aforementioned embodiments, the leakage characteristic may comprises an amount of leakage voltage over time.

### BRIEF DESCRIPTION OF THE DRAWINGS

The invention will be described in greater detail with reference to the accompanying drawings which represent preferred embodiments thereof, wherein:

FIG. 1 is a schematic diagram of a piezo-electric transducer system in accordance with an embodiment of the present disclosure;

FIGS. 2A and 2b are schematic diagrams of a piezo-electric transducer driver circuits in accordance with an embodiment of the present disclosure;

FIG. 3 is a schematic diagram of a piezo-electric transducer system in accordance with an embodiment of the present invention;

FIG. 4 is a plot of output voltage vs time for the piezo-electric transducer system of FIG. 3 without executing the sense/drive algorithm;

FIG. 5 is a plot of output voltage vs time for the piezo-electric transducer system of FIG. 1 or 3 while operating the sense/drive algorithm;

FIG. 6 is a flow chart of an algorithm for controlling a piezo-electric transducer;

FIG. 7 is a schematic diagram of a multi-channel piezo-electric transducer system in accordance with another embodiment of the present disclosure;

FIG. 8 is a plot of voltage vs time for a piezo-electric sensing voltage for a conventional multi-channel piezo-electric transducer system; and

FIG. 9 is a plot of voltage vs time for a piezo-electric sensing voltage for the multi-channel piezo-electric transducer system of FIG. 7;

FIG. 10 is a plot of threshold force vs press speed with and without leakage compensation;

FIG. 11 is a plot of voltage vs time for a piezo-electric sensing voltage during a characterizing test;

FIG. 12 is a plot of voltage vs time for a piezo-electric sensing voltage for a first embodiment of a leakage compensation system; and

FIG. 13 is a plot of voltage vs time for a piezo-electric sensing voltage for a second embodiment of a leakage compensation system.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art.

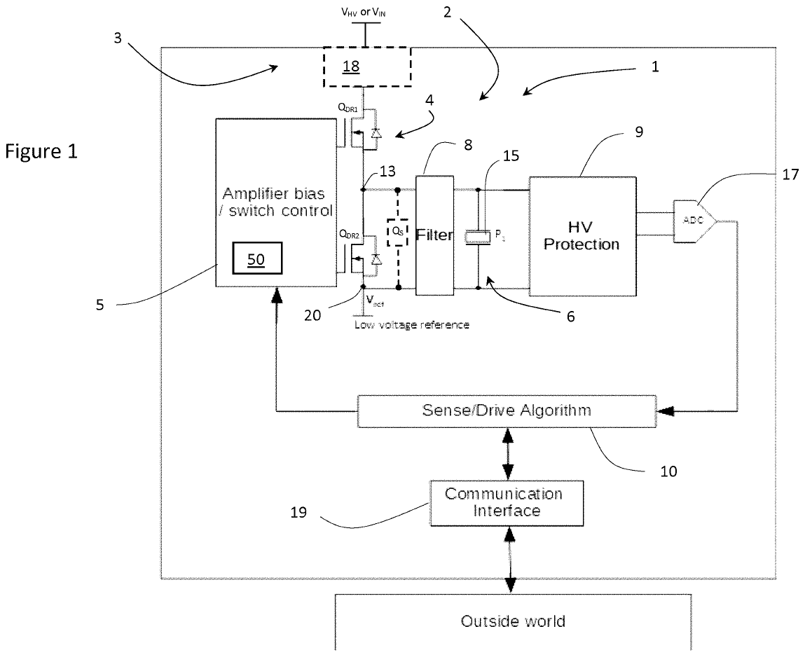

FIG. 1 illustrates a piezo-electric transducer system 1 that may use a piezo-electric transducer P1 or some other form of transducers, such as electro-active polymer transducers, both as an actuator for driving, e.g. haptic feedback, and for force sensing, e.g. a switch or level control. Typically, circuits are designed to either drive the piezo-electric transducer P1 or sense a force applied to the piezo-electric transducer P1. When combining both functionalities in the same system and/or when operating a plurality of piezo-electric transducers simultaneously, complications arise from the parasitic paths created by the output devices (transistors) of the driver section of the system. Conventional systems, such as those disclosed in EP 3065029 (Kyocera), require four or five switches in addition to the drive and detection units to change between the different modes and isolate the parasitic paths.

The piezo-electric transducer system 1, includes a piezo-electric transducer circuit 2 comprising an input stage 3, a driver stage 4, an amplifier bias/switch control 5, and an output stage 6, including the piezo-electric transducer P1 or some other electro-active transducer. The piezo-electric transducer circuit 2 may be implemented in a single chip or using discrete parts due to the high power to process. The input stage 3 may include or be connected to a high-voltage voltage source VHV, typically between 20 V and 200 V, whereby the driver stage 4 simply drives the desired driver voltage VDR at a value between VHV and Vref. VDR may have the same magnitude as the high voltage source VHV or a stepped down magnitude, e.g. typically between 20 V and 80 V, forming the output voltage Vout at an output node 13 and to the output stage 6, e.g. across the piezo-electric transducer P1.

Alternatively, the input stage 3 may include or be connected to a low-voltage source VIN, such as a battery, typically between 2 V and 10 V, preferably 3.6 V to 5V, whereby the driver stage 4 also includes a power converter circuit 18 for converting the input voltage Vin to a higher peak, e.g. 30V-60V, AC driver voltage VDR. The power converter circuit 18 may comprise a plurality of switches, e.g. power converting transistors, and other electrical components, such as inductors and capacitors for amplifying the input voltage Vin to the desired driver voltage VDR.

The driver stage 4 may include one or more driver stage switches, e.g. first and second driver stage switches QDR1 and QDR2, such as first and second driver transistors, configured to bias the output node 13 with the required driver voltage VDR as the output voltage Vout for selectively transmitting the driver voltage VDR to the output stage 6, The second driver stage switch QDR2, extending between the output node 13 and reference node 20 (Vref) across the piezo-electric transducer P1 may also be configured for discharging the output node 13, e.g. back to 0V, after the driver stage 4 actuates the piezo-electric transducer P1 to enable normal sensing to proceed.

The amplifier bias/switch control 5 may comprise a controller 50, which controls the bias of the driver stage switches, e.g. the first and second driver stage switches QDR1 and QDR2, and if necessary the power converter switches. There are many ways to design the amplifier bias/switch control 5 to achieve a desired system specification. The controller 50 may also continuously sense the output voltage Vout, e.g. from the output node 13, for determining whether an external force has been applied to the piezo-electric transducer P1, e.g. by a user. In particular, the controller 50 determines whether the external force, and a resulting sensed voltage VSens from the piezo-electric transducer P1 measured as the output voltage Vout, exceeds an activation level, which results in the controller 50 activating the driver stage 4 to transmit the driver voltage signal VDR to the piezo-electric transducer P1 to generate a haptic response, e.g. vibration, translation and/or noise. The output voltage Vout is the voltage measured between the output node 13 and the reference node 20 (reference voltage Vref), which may comprise the sensed voltage VSens and/or the driver voltage signal VDR, depending on the current activities of the piezo-electric transducer system 1. The controller 50 may also activate the driver stage 4 to transmit the driver voltage signal VDR to the piezo-electric transducer P1 to generate a haptic response, in response to an external instruction signal from the outside world, e.g. a host electronic device incorporating the piezo-electric transducer system 1, such as a smart watch, a smart phone or tablet.

A passive filter 8 may be provided in the output stage 6, e.g. parallel to a load 15, such as one or more piezo-electric transducers P1, configured to filter the output, e.g. the driver voltage signal VDR, of the piezo-electric transducer circuit 2. The passive filter 8 is optional, but could be used without changing the high-level behavior of the piezo-electric transducer system 1. The passive filter 8 may be inserted between the driver stage 4 and the load 15 to remove high-frequency content in the driver voltage signal VDR before reaching the load 15. The passive filter 8 is particularly useful when the driver stage 4 uses a Class-D amplifier topology.

The reference voltage Vref represents the voltage reference for the load 15, e.g. the piezo-electric transducer P1. The reference voltage Vref may be ground or any other convenient voltage in the system, e.g. Vin.

A high voltage protection circuit 9, which may be included in the amplifier bias/switch control 5 or separate therefrom, comprises an electronic architecture that either adapts or blocks the output voltage Vout from the output node 13, i.e. the sensed voltage signal VSens from the load 15 and/or the driver voltage VDR from the driver stage 4, to an appropriate, e.g. safe, voltage level for one or more analog to digital converters (ADC) 17. The one or more ADC 17 convert the output voltage Vout, i.e. the sensed voltage signal VSens and/or the driver voltage signal VDR, to a digital representation, and conveys the corresponding digital value of the magnitude of the sensed voltage signal VSens and/or the driver voltage signal VDR to the controller 50 in the amplifier bias/switch control 5.

A sense/drive algorithm 10, which may be in the form of computer hardware and/or computer software stored on non-transitory memory, either as part of the piezo-electric transducer system 1 or in a separate memory storage device, enables the amplifier bias/switch control 5, and in particular the controller 50, to accurately sense the load, e.g. the sensed voltage VSens across the piezo-electric transducer P1, even when the sensed voltage signal VSens would trigger a parasitic conduction path, e.g. forward bias a body diode, of any of the driver stage switches directly connected to the piezo-electric transducer P1, e.g. the first or the second driver stage switches QDR1 and QDR2, during various applications. For example: during removal of a force on the piezo-electric transducer P1 after actuation of piezo-electric transducer P1, a negative voltage, e.g. −2 V, may be generated, which causes parasitic leakage in at least one of the driver stage switches, e.g. the second driver stage switch QDR2, and prevents the controller 50 from accurately determining the force that has been applied to the piezo-electric transducer P1, in particular if the force and resulting sensed voltage VSens is large enough to exceed the activation level.

Accordingly, a sensing switch QS may be provided to repeatedly zero the output voltage Vout, i.e. the sensing voltage VSens, from the output node 13 to enable a compilation of voltage segments used to determine the actual sensing voltage VSens. For example, the sensing switch QS, e.g. a sensing transistor, may be connected across the piezo-electric transducer P1, e.g. the output node 13, and the reference node 20 (reference voltage Vref), e.g. Vin or ground, with a control terminal, e.g. a gate, connected to the controller 50, which enables the sensed voltage VSens across the piezo-electric transducer P1 to be zeroed, i.e. discharged, to the reference voltage Vref, when needed, as hereinafter disclosed in detail. The second driver stage switch QDR2 or some other suitable switch, e.g. transistor, already provided in the piezo-electric transducer system 1 may also be used as the sensing switch QS.

A communication interface 19 enables the piezo-electric transducer system 1 to receive and send signals relating to driving the one or more piezo-electric transducers P1 and/or sensing a force application on the one or more piezo-electric transducers P1 to and from the outside world, e.g. the host electronic device incorporating the piezo-electric transducer system 1, such as a smart watch, a smart phone or tablet. Activation of the one or more piezo-electric transducers P1 may provide an indication to the host device of any form of user input, e.g. on/off, volume up, volume down, enter, etc.

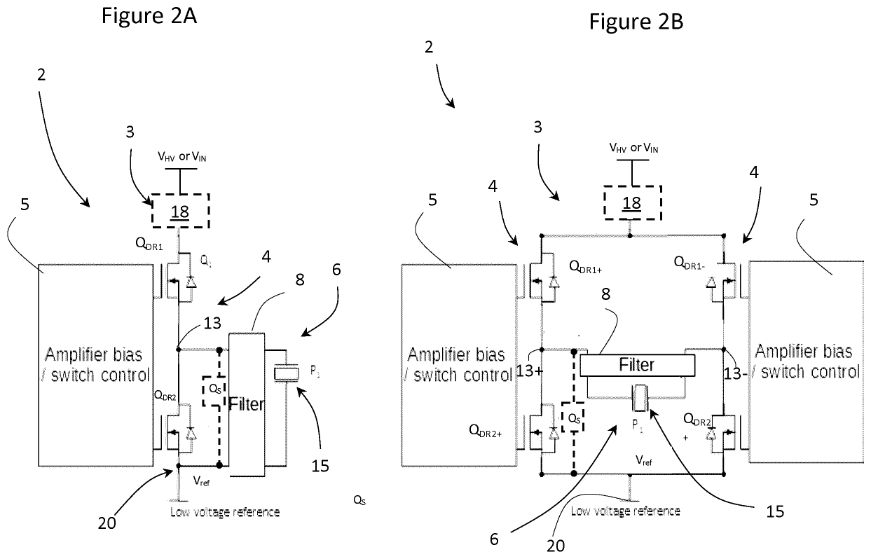

FIGS. 2A and 2B represent two embodiments for piezo-electric transducer circuits 2. The driver stage 4 may be based on different amplifier architectures, e.g. Class-A, Class AB, Class D, etc, but from an architecture and component perspective, the load 15, e.g. the one or more electro-active or piezo-electric transducers P1, is connected between the output node 13 and the reference node 20 or reference voltage Vref for a unipolar output (FIG. 2A). For a bipolar output, e.g. FIG. 2B, each end of the load 15 is connected at a different output node 13+ and 13−. In all cases, the output voltage Vout at the output nodes 13+ and 13−, e.g. the driver voltage signal VDR and/or the sensed voltage signal VSens, may be controlled minimally by one or more switches, such as QDR1+, QDR1−, QDR2+, and QDR2−, e.g. transistors, enabling the current to flow between the high voltage supply VHV or Vin (or current source) and the reference voltage Vref, e.g. reference node 20 across the load 15.

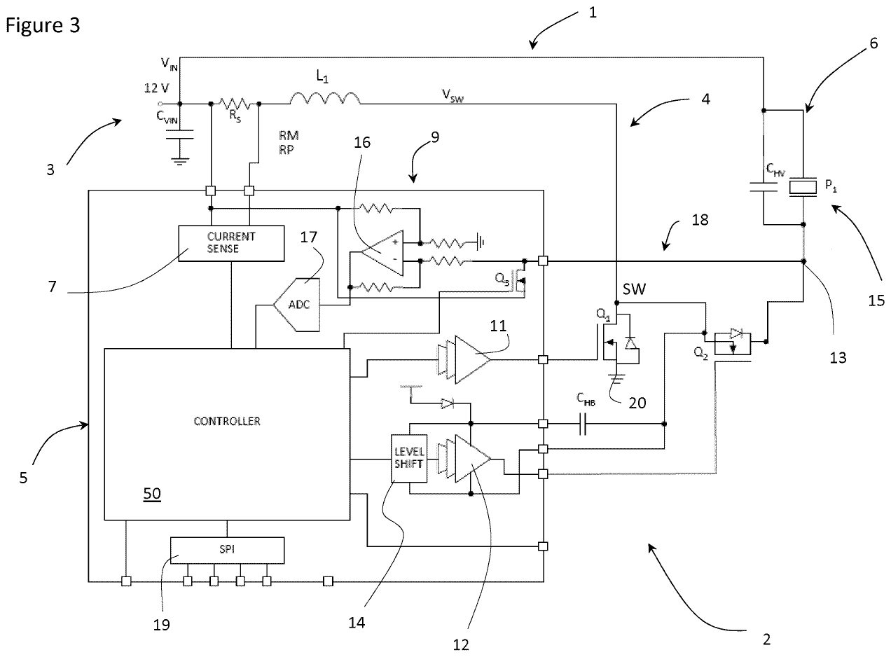

One exception is presented in FIG. 3, which illustrates a two-transistor architecture as described in U.S. Pat. No. 10,199,555, issued Feb. 5, 2019 in the name of Simon Chaput, incorporated herein by reference. The two-transistor driver stage 4 enables the sinking and sourcing of current in the load 15 through the second driver stage switch Q2. In all figures, the body diode of the first and second driver stage switches Q1 and Q2 are represented by a diode symbol to show explicitly the parasitic path. For all transistors, if a conducting terminal to conducting terminal, e.g. Drain-Source (VDS), voltage becomes negative enough, e.g. above the leakage or turn-on voltage of the body diode of the second driver stage switch Q2 connected to the load 15, the current will start to flow from the first conducting terminal, e.g. source, to the second conducting terminal, e.g. drain, via the body diode. The leakage voltage at which the current will start to flow in the diode may be between 0.2 V and 0.7 V typically depending on the exact device and semiconductor technology used. To ease the explanation, we are assuming an N-type MOS transistor is used; however, a skilled person in the art will recognize that a similar situation happens with other transistors, e.g. P-type devices.

The piezo-electric transducer system 1, includes the piezo-electric transducer circuit 2 comprising the input stage 3, the driver stage 4, the amplifier bias/switch control 5, and the output stage 6. The piezo-electric transducer system 1 may be implemented in a single chip or using discrete parts due to the high power to process. The input stage 3 may be connected to the voltage source VIN, such as a battery, typically with an input voltage Vin of between 6 V and 20 V, preferably 9V to 16V. The driver stage 4 may be comprised of the power converter circuit 18 including a forward-boost/reverse-buck converter that generates a clean sine waveform. The power converter circuit 18 of the driver stage 4 may include an inductor L1 connected to the voltage source VIN, and the driver stage switches, e.g. driver stage switches consisting of a first low side switch Q1 connected between the inductor L1 and ground, and a second driver switch Q2 connected between the inductor L1 and the output stage 6. The control terminal, e.g. gate, of the transistor in the first driver stage switch Q1 may be connected to a first gate driver 11 in the amplifier bias/switch control 5, and the control terminal, e.g. gate, of the transistor in the second switch Q2 may be connected to a second gate driver 12 in the amplifier bias/switch control 5. Both the first gate driver 11 and the second gate driver 12 may be connected to the controller 50, which sends control signals to the first and second gate drivers 11 and 12 to control operation of the first and second driver gate switches Q1 and Q2, respectively.

While the aforementioned embodiment is described being used for sine waveforms, persons having ordinary skill in the art will appreciate the embodiments described herein may operate upon arbitrary and complex analogue waveforms, for example, square, triangular, AM modulated, FM modulated, and are not limited to operating upon sine waveforms.

The input stage 3 may include a filter capacitor (CVIN) connected across the low voltage source VIN and ground, and a sense resistor (RS) connected between the low voltage source VIN and the single inductor L1. The single inductor L1 may be connected between the sense resistor RS and a switching node SW of the driver stage 4. A current sensor 7, which may be included in the amplifier bias/switch control 5, may be connected on either side of the sense resistor RS and to the controller 50 for measuring the current, and/or the voltage entering the inductor L1 and the driver stage 4. The current sensor 7 provides bidirectional current sensing in all possible switching condition during operation, for example, borderline conduction mode, discontinuous conduction mode and continuous conduction mode. The current feedback sensor 7 ensures the first driver stage switch Q1 and the second driver stage switch Q2 turn on/off at the right time to avoid high switching losses at the switching node SW.

The second driver stage switch Q2 may be an N-type transistor including a first conducting terminal, e.g. source, connected to the switching node SW and referenced to the switching node voltage Vsw, a second conducting terminal, e.g. drain, connected to the load 15, and a third control terminal, e.g. gate, connected to the controller 50. In order to control the control terminal appropriately, a level shift block 14, which may be included in the amplifier bias/switch control 5, translates a control signal from the controller 50 referenced to ground into a signal referenced to a switching node voltage Vsw at the floating switching node SW. Under the first embodiment the level shift block 14 enables scaling of a digital control signal amplitude from a digital logic level to a higher amplitude suitable for the second driver stage switch Q2, for example, scaling from 1.8V to 5V.

The level shift block 14 may change the reference voltage Vref, i.e. the reference node 20, for the driver voltage signal VDR from ground to an arbitrary floating node, in this case, the switching node SW. While FIG. 3 illustrates an N-type transistor for the first and second driver stage switches Q 1 and Q2, in an alternative embodiment, a different type of switch, e.g. a P-type transistor, may be used with similar requirement for a level shift block. For P-type switch transistors, the level shift block 14 may use a floating bootstrap supply (not shown) to provide the desired level for the output of the level shift block 14.

Although desirable that the differential drive voltage signal (VDR−VIN) be very clean, it is not necessary for the output voltage Vout, e.g. the driver voltage signal VDR or the sensed voltage signal VSens at the output node 13 to be referenced to ground. The high voltage protection circuit 9 may include a difference amplifier 16, which measures continuously the differential drive voltage between the reference voltage Vref and the output voltage Vout at output node 13, i.e. the driver voltage signal VDR and/or the sensed voltage signal VSens, and converts the difference to a single-ended signal fed to the analog-to-digital converter (ADC) 17, which provides a digital representation of the output voltage Vout, i.e. the drive voltage signal VDR and/or the sensed voltage VSens to the controller 50.

The communication interface 19 may comprise a serial peripheral interface (SPI), which implements a communication protocol that enables an external microcontroller (or other device, for example, a computer) to send/receive information to/from the piezo-electric transducer circuit 2 via the controller 50, such as a reference waveform and internal settings used for the particular implementation. It should be noted SPI is an example of one of several digital communication protocols that may be implemented to interface with the controller 50. Other examples of a communication interface include, but are not limited to I2C, TDM, and I2S.

The inductor L1, may be a 10 μH inductor. The inductor L1 value may be selected in order to: (1) achieve a target distortion, e.g. lower inductance increases switching frequency and decreases distortion/THD+N, and/or (2) minimize the switching frequency, e.g. in general, a lower switching frequency corresponds to lower power consumption.

The first and second driver stage switches Q1 and Q2 may be of the same type, which may be the most practical choice for an integrated circuit (IC) implementation, although embodiments with mixed switches may be used. The first and second driver stage switches Q1 and Q2 may comprise, for example, GaN, PMOS, among other possible switches.

The output stage 6 may be referenced to the input voltage Vin instead of GND. The output stage 6 may include the filter 8, e.g. a filter capacitor CHV, and the load 15, for example one or more of the piezo-electric transducers P1. Therefore, to obtain 0 V differential across the piezo-electric transducer P1, e.g. in a resting state, the driver voltage signal VDR and the reference voltage Vref, which is equal to the input voltage Vin, may be equal. Increasing the driver voltage signal VDR across the load 15 above the input voltage Vin, e.g. in an active state, may be provided by the power converter circuit 18 of the driver stage 4.

In the piezo-electric transducer system 1 illustrated in FIG. 3, the conversion ratio, e.g. voltage amplification, of the power conversion circuit 18 may be greater than 10×, and preferably between 10× and 20× for a 50 to 120 VAC driver voltage signal VDR from a, e.g. 3.6-5 VDC input voltage Vin. Initially, the controller 50 turns the first driver stage switch Q1 on and the current in the inductor L1, which is connected to the reference node 20, e.g. ground, ramps up linearly. When the controller 50 turns the first driver stage switch Q1 off, the switching node voltage VSW at the switching node SW increases the driver voltage signal VDR to the desired output voltage Vout value and current flows from the inductor L1 through the second driver stage switch Q2 to increment the output voltage Vout. Here, a body diode of the second driver stage switch Q2 may turn on or the second driver stage switch Q2 may turn on connecting the switching node SW to the load 15 and charges the load 15, e.g. the piezo-electric transducer P1. When the inductor L1 current reaches 0, the second driver stage switch Q2 is turned off and the switching node voltage VSW goes back to 0 V. The controller 50 alternates the state of the first driver stage switch Q1 and the second driver stage switch Q2 to control the amount of energy sent or extracted from the load 15. In the power converter circuit 18 of the driver stage 4, since the boost converter voltage gain is most of the time larger than 2, the switching node voltage VSW may decrease to a little bit less than 0 V and turns on the body diode of the first driver stage switch Q1. Thereupon, the first driver stage switch Q1 is turned on again under zero voltage switching condition (ZVS), thus reducing the switching losses associated to the parasitic capacitance at the switching node SW.

When the second driver stage switch Q2 turns off, the first driver stage switch Q1 turns on in ZVS condition. Then the first driver stage switch Q1 stays on until the inductor L1 accumulates enough energy to charge the switching node voltage VSW to the driver voltage signal VDR. When the first driver stage switch Q1 turns off, the switching node voltage VSW rings to the driver voltage VDR and the second driver stage switch Q2 is turned on under ZVS condition thus reducing switching losses.

A potential issue with piezo-electric transducer systems is an inability to accurately sense negative voltages across the piezo-electric transducer P1, which are limited by a leakage or turn-on voltage Vto, e.g. −0.3V, of a parasitic conduction path, e.g. a body diode, of at least one of the driver stage switches, e.g. the second driver stage switch Q2. When the sensed voltage signal VSens across the piezo-electric transducer P1 makes VSens−Vsw become less than the turn-on voltage Vto set by the leakage of the body diode in the driver stage switch, e.g. the second driver stage switch Q2, the output voltage Vout read by the controller 50 is limited approximately to that turn-on voltage Vto because all other charges created by the piezo-electric transducer P1 are replaced by the body diode conduction which limits the change in voltage.

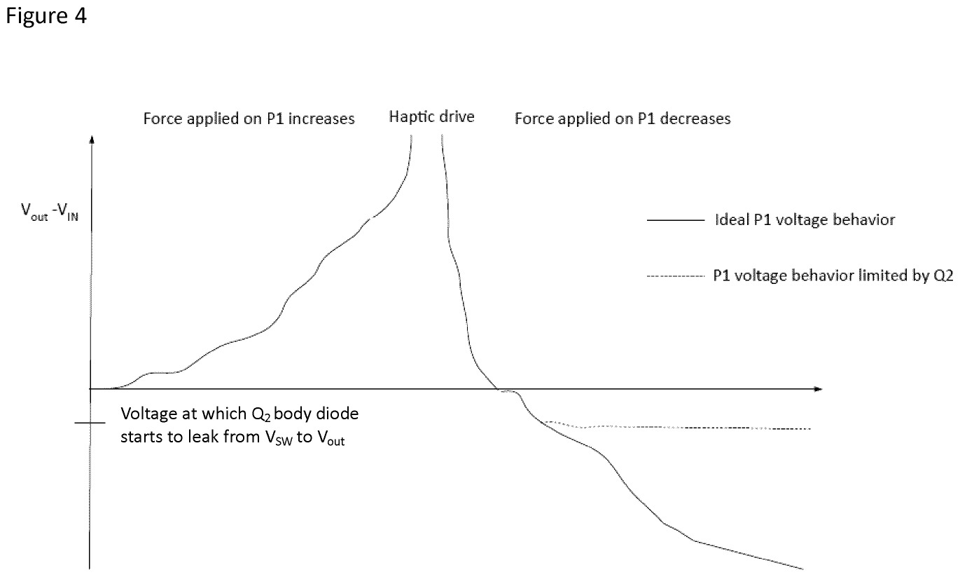

With reference to FIG. 4, an initial application of a force on the piezo-electric transducer P1 results in the generation of a gradually increasing, e.g. positive, sensed voltage signal VSens across the piezo-electric transducer P1 and the output voltage Vout read by the controller 50 following the sensed voltage signal VSens, i.e. increasing from zero to a maximum voltage, e.g. 2.0 V. When the sensed voltage signal VSens reaches the activation level, e.g. 1.8 V, a driver voltage VDR is forced on the piezo-electric transducer P1 to generate a haptic feedback event increasing the output voltage Vout by the driver voltage VDR, e.g. to over 50 V. The haptic event terminates by setting the voltage Vout across the piezo-electric transducer P1 to 0 V. However, releasing the force or pressure on the piezo-electric transducer P1 now generates a gradually decreasing sensed voltage signal VSens and output voltage Vout, which may become a negative voltage less than the turn on voltage Vto, e.g. −0.3 V, of the body diode of one of the driver stage switches, e.g. the second driver stage switch Q2. Unfortunately, at lower voltages, i.e. larger negative voltages, the sensed voltage signal VSens across the piezo-electric transducer P1 becomes less than an upper limit voltage set by the leakage or turn on voltage Vto of the body diode, e.g. in the second driver stage switch Q2, and the output voltage Vout read by the controller 50 is limited to that upper limit voltage because all other charges created by the piezo-electric transducer P1 are replaced by the body diode conduction which limits the change in measured output voltage Vout.

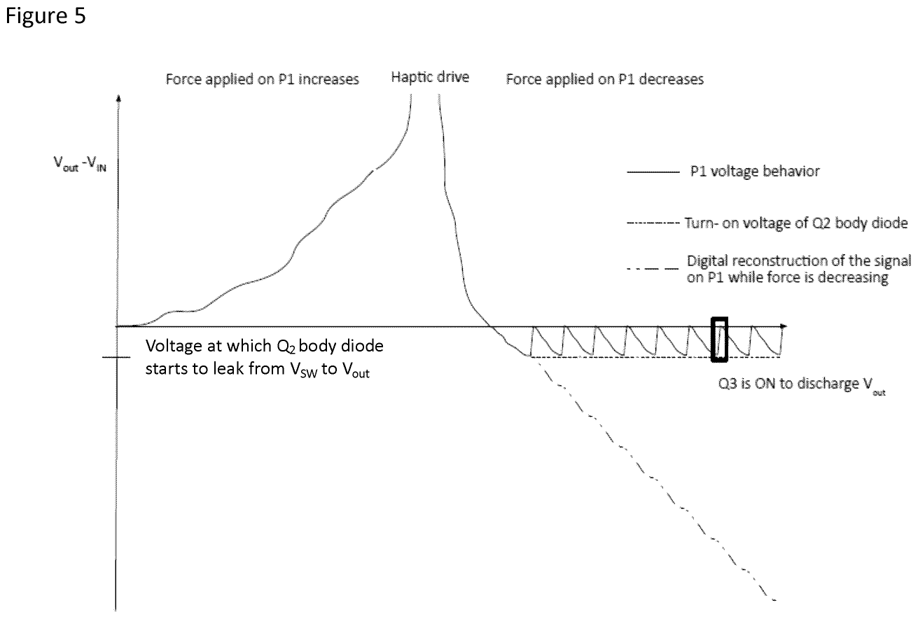

FIG. 5 illustrates a typical use case for a haptic system relative to the base architecture with the addition of the sensing switch, e.g. sensing transistor, QS, which may be in the form of an existing driver stage switch, e.g. the second driver stage switch QDR2 (FIG. 1), an added sensing switch QS (FIG. 1), or a third switch, e.g. transistor, Q3 (FIG. 3) to enable the sense/drive algorithm 10 to be executed by the controller 50. The sensed voltage signal VSens, across the load 15, e.g. piezo-electric transducer P1, increases normally in the positive direction when a user applies a force on the piezo-electric transducer P1 until the sensed voltage signal VSens reaches the activation level set to launch a haptic effect. When the activation level is reached, the different driver stage switches, e.g. the first and second driver stage switches Q1 and Q2, are biased by the controller 50 to generate the high-voltage drive voltage signal VDR on the piezo-electric transducer P1. The piezo-electric transducer P1 transforms the drive voltage signal VDR into a displacement or force via the piezo-electric transducer P1 that is felt by the user. The sensed voltage signal VSens on the piezo-electric transducer P1 is driven back to 0 at the end of the haptic effect using at least one of the driver stage switches, e.g. the second driver stage switch Q2. Then when the user removes the force from the piezo-electric transducer P1, the sensing voltage signal VSens across the piezo-electric transducer P1 becomes negative. Accordingly, the sense/drive algorithm 10 may be used by the controller 50 to obtain an accurate representation, e.g. digital value, of a total sensed voltage VSensT, pieced together from segments of the output voltage signal Vout, e.g. the sensed voltage VSens, which are continually sensed, e.g. 1 kS/s-10 kS/s, providing a current interim digital representation at each sample, and then repeatedly discharged by the sensing switch QS providing a full segment digital representation each discharge, whenever the output voltage, i.e. the sensed voltage VSens, approaches the turn on voltage of the parasitic conduction path, e.g. every 2-4 ms. While it is not depicted in FIG. 5, once the sensed voltage signal VSens or VSensT reaches the activation level, e.g. less than −1.8 V, or a magnitude (absolute value) greater than the magnitude (absolute value) of the activation level value, a following haptic effect may be triggered.

The sensing switch, e.g. sensing transistor QS, comprised of the third switch Q3 may be connected between the piezo-electric transducer P1 and the reference voltage, e.g. Vref, Vin or ground, with the control terminal, e.g. gate, connected to the controller 50, which enables the output voltage Vout, e.g. the sensed voltage VSens, across the piezo-electric transducer P1 to be zeroed, i.e. discharged to the reference voltage Vref, when needed. Accordingly, the third switch Q3 may be activated by the controller 50 to zero the output voltage Vout, e.g. the sensed voltage VSens across the piezo-electric transducer P1, each time the output voltage Vout reaches a predetermined threshold voltage Vth, e.g. before reaching a trigger level of a parasitic conductive path, e.g. the turn-on voltage, (−0.3 V) of the body diode of the second switch Q2. As a result, each time the output voltage Vout based on VSens reaches the threshold voltage Vth, e.g. −0.25 V, at some level greater than the negative turn-on voltage, (or less than a positive turn-on voltage) a full voltage segment is generated and converted into a digital value by the controller 50, added to an accumulated sensed voltage value Vacc, and then discharged by activation of the sensing switch QS. A plurality of voltage segments, e.g. having a magnitude approximately the same as the threshold voltage (0.25 V) but usually greater depending on sample rate, are sequentially generated and then discharged. The sense/drive algorithm 10 executed by the controller 50 may determine, e.g. provide a reconstruction (digital) of, the sensed voltage VSens across the piezo-electric transducer P1 from the plurality of voltage segments and, when accuracy is essential, the interim digital representation from the current sensed voltage VSens, forming a digital value representing a total accumulated sensed voltage VSensT. For example: the sense/drive algorithm executed by the controller 50 may add up (digitally) the different voltage segments (See FIG. 5) of the output voltage Vout or add up (digitally) the number of times the output voltage Vout moves between 0 and the threshold voltage Vth, thus providing a much better sensing performance for negative voltages across the piezo-electric transducer P1. Accordingly, the controller 50 may be able to determine when the user has fully released the piezo-electric transducer P1 and/or set a more accurate minimum negative voltage for resetting and determining a secondary force application, e.g. greater in magnitude than the activation level, on the piezo-electric transducer P1. While the architecture in FIG. 3 required the addition of the sensing switch QS, e.g. the third switch Q3, to be able to implement the sense/drive algorithm 10, some architectures may not need an extra component, e.g. the third switch Q3, to be added to implement the method, but a change in the control algorithm utilizing an existing component, e.g. the second switch Q2, may be sufficient.

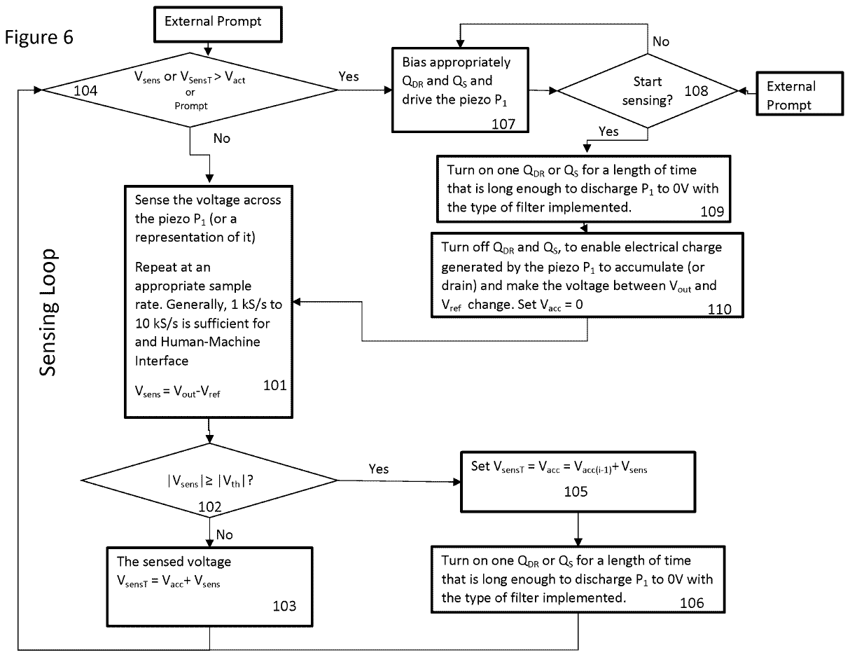

With reference to FIG. 6, the controller 50 may execute the sense/drive algorithm 10 in the following manner. During normal operation, the controller 50 is executing the sensing loop including sensing step 101, preferably at a typical rate between one thousand samples per second and ten thousand samples per second (1 kS/s and 10 kS/s) for applications in Human-Machine Interfaces generating interim digital representations of the current sensed voltage VSens. Before entering the sensing loop, the first piezo-electric transducer P1 is connected to the reference voltage Vref on one side, e.g. Vin, with the driver stage switches, e.g. QDR1, QDR2, Q1, or Q2, and the sensing switches QS switched off creating a high impedance node 13, and enabling the controller 50 to continuously determine the output voltage Vout, comprised of only the sensed voltage VSens i.e. for sensing a force application on the piezo-electric transducer P1. In step 101, the sensed voltage VSens across the piezo-electric transducer P1 (Vout−Vref) is sensed. The value of the accumulated voltage Vacc is initially set to 0 V, and the controller 50 senses and receives an interim digital representation of the sensed voltage VSens at the aforementioned sample rate, e.g. every 0.1 to 1 ms.

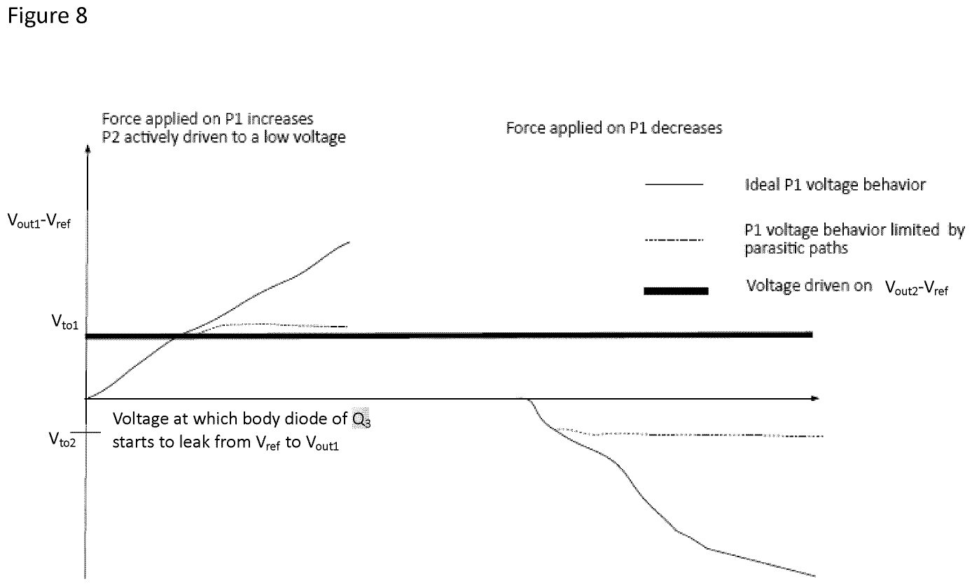

In decision step 102, the controller 50 determines if the voltage across the piezo-electric transducer P1 is approaching the trigger level of any one of the parasitic paths in the circuit, by, e.g. determining if or when the sensed voltage signal VSens, preferably the absolute value thereof, is above the threshold voltage Vth, preferably the absolute value thereof, or between the threshold voltage Vth and the turn-on voltage Vto of some or all of the parasitic paths. As shown in FIG. 5, a single parasitic path existed in the implementation of FIG. 3 when the sensed voltage signal VSens across the piezo-electric transducer P1 was becoming negative enough. However, FIGS. 1 and 8 show cases in which an upper bound and a lower bound on the sensed voltage signal VSens across the piezo-electric transducer P1 may trigger parasitic paths. Consequently, decision step 102 verifies if and when a parasitic path will be triggered by the current sensed voltage signal VSens across the piezo-electric transducer P1. While the decision shows a single condition, in a real application, multiple conditions may be tested. If none of the conditions are true, i.e. the sensed voltage signal VSens across the piezo-electric transducer P1 is not close to triggering a parasitic path, i.e. not near the threshold voltage, the algorithm 10 proceeds to totalling step 103, in which the total sensed voltage signal VSensT or a new accumulated voltage Vacc(i) is equal to the sum of the current value of the accumulated voltage Vacc(i−1) (result of accumulation step 105 as hereinafter described or 0 V if no parasitic path previously triggered) plus the current measured sensed voltage VSens across the piezo-electric transducer P1, as per the current sample, i.e. the interim digital representation. The sensing loop then proceeds to comparison step 104, where the value of the sensed voltage VSens or the total accumulated sensed voltage VSensT is compared to one or more arbitrary activation level(s) Vact of the piezo-electric transducers P1. Depending on the result of the comparison step 104, the algorithm 10 may continue in the sensing loop (VSensT<Vact) until the total accumulated sensed voltage VSenT reaches the activation level Vact of the piezo-electric transducer P1 or the algorithm 10 exits the sensing loop and enters the driving loop to drive the driver stage 4 and the piezo-electric transducer P1, in driver step 107, as hereinafter described, for other reasons, e.g. an external prompt from the external device.

While the algorithm 10 cycles through the sensing loop, one of the conditions, e.g. approaching the triggering of one of the parasitic paths and reaching Vth, at the decision step 102 (Vsens≥Vth) may become true. When that happens, the algorithm 10 will proceed to accumulation step 105. The value of the total sensed voltage VSensT or alternatively the new accumulated voltage Vacc(i) will be updated as the old Vacc(i−1) added to the sum of the current sensed voltage VSens (or Vout−Vref) measured across the piezo-electric transducer P1 based on the current sample (current interim digital representation), and the current value of the accumulated voltage Vacci, e.g. based on the number of previously discharged sensed voltage signals VSens (digital representation of voltage segments). When the algorithm 10 enters the sensing loop, the value of the accumulated voltage Vacc is always 0 and its value is updated every time it goes through the accumulation step 105 so that the controller 50 may determine the total accumulated sensed voltage VSensT generated by the piezo-electric transducer P1 as depicted in FIG. 5 and J2L 1S9. The accumulation Step 105 is a special case in which the total accumulated sensed voltage VSensT equals the new accumulated voltage Vacc. Then in discharge step 106, the sensing switch (e.g. QDR2 or QS) is used to discharge the voltage across the piezo-electric transducer P1 to 0V. The sensing switch QS is turned on long enough to ensure a proper discharge with the filter 8 that may be implemented. In comparison step 104, after each sample, when the controller 50 senses a total accumulated sensed voltage VsensT, which may be an accumulated voltage Vacc(i)+a current sensed voltage VSens, i.e. an interim digital representation thereof, greater than the activation level Vact, i.e. a force application on the piezo-electric transducer P1 of large enough magnitude, OR when an external prompt is sent from the host device at decision step 102, the controller 50 switches to driver step 107 in the driving loop.

In driver step 107, the controller 50 may activate the driver voltage signal VDR with the driver stage switches, e.g. Q1 and Q2 or QDR1 and QDR2, and the sensing switches, e.g. QS, properly biased, to generate a haptic response in response to a force application on the piezo-electric transducer P1 or some other notification. During the driving step 107 the driver stage switches, e.g. the first and second switches Q1 and Q2, and the sensing switching Qs, e.g. the third switch Q3, are biased appropriately by the controller 50 to drive the first piezo-electric transducer P1 to generate a haptic response to the user, e.g. some form of notification from the device, such as a force application on the piezo-electric transducer P1 or in response to an external notification, e.g. a telephone call. With reference to repeat step 108, at the end of the haptic effect, the sense/drive algorithm 10 may repeat the driving step 107, if for example an external prompt from the host device requires another haptic response or may revert back to the sensing loop and wait for a user or device input. Prior to returning to the sensing loop at step 101 the controller 50 may execute first and/or second reset steps 109 and 110 by first turning on the sensing switches QS and or driver stage switches, e.g. Q1 and Q2 or QDR1 and QDR2, to discharge the output voltage Vout across the piezo-electric transducer P1, e.g. to 0 V (step 109) and then by turning off the driver stage and sensing switches, e.g. Q1 and Q2 or QDR1 and QDR2, and QS at reset step 110, to enable electrical charge generated by the piezo-electric transducer P1 to accumulate (or drain) and make the voltage between the output node 13 (Vout) and the reference voltage Vref, e.g. VIN, change, so that the controller 50 accurately receives the output voltage Vout indicative of the sensed voltage signal VSens across the first piezo-electric transducer P1.

To avoid parasitic leakage, the controller 50 may determine when the output voltage Vout is between the threshold voltage Vth and the turn on voltage Vto for each switch, e.g. transistor, connected to the piezo-electric transducer P1, e.g. first and second driver stage switches QDR1 and QDR1. For example, for negative voltages, the controller 50 may determine when the output voltage Vout is less than the threshold voltage Vth. For positive voltages, the controller 50 may determine when the output voltage Vout is greater than the threshold voltage Vth. Alternatively, the controller 50 may determine when the magnitude (or absolute value) of the output voltage |Vout−Vref| is greater than the magnitude (or absolute value) of the threshold voltage |Vth|. With reference to FIG. 3, the threshold voltage Vth (e.g. −0.25 V) corresponds to a voltage greater than the turn on voltage Vto (e.g. −0.3 V) of the second switch Q2 but other threshold voltages for other switches are within the scope of the invention.

With reference to FIG. 1, the decision step 102 may be applied with the proper threshold voltage Vth relating to the corresponding turn on voltages Vto for all the driving switches or at least some of them, e.g. the driver stage switches (e.g. QDR1, QDR2, Q1 and Q2) directly connected to the piezo-electric transducer P1 or the driver stage switch with the turn on voltage Vto with the lowest magnitude or highest value. In more general terms, decision step 102 asks if the output voltage Vout value approaches a value which would trigger an existing parasitic path in the piezo-electric transducer circuit 2 by comparing the sensing voltage signal VSens to a threshold voltage Vth. The number of parasitic paths in the piezo-electric transducer circuit 2 may vary. In the embodiment of FIG. 1 there are 2 paths, e.g. QDR1 and QDR2, in the embodiment of FIG. 2b, there are 4 parasitic paths, e.g. QDR1+, QDR1−, QDR2+ and QDR2−, and in the embodiment of FIG. 3 there is 1 parasitic path, e.g. Q2.

When the answer to decision step 102 is YES for at least one tested parasitic path, a new or current accumulated voltage Vacc(i) is computed by the controller 50 at accumulation step 105 as the sum of the previous accumulated voltage Vacc(i−1) plus the current voltage segment VSens, i.e. (Vout−Vref)i, each voltage segment may approximately equal to or slightly larger than the magnitude of the threshold voltage Vth. Each voltage segment is converted into a digital representation, which are added up by the controller 50. The total reconstructed voltage VsensT in that situation may be equal to the sum Vacc(i−1) of the digital representations of the voltage segments plus the digital representation of the current voltage segment, VSens or (Vout−Vref).

Each time the sensed voltage VSens (Vout−Vref) reaches a parasitic condition in decision step 102 and the accumulation step 105 is executed, a discharge step 106 may be executed by the controller 50, during which the controller 50 turns on at least one of the sensing switches QS, e.g. the second driver switch QDR2 or the third switch Q3, and zeroes, e.g. discharges, the output voltage Vout−Vref to 0 V therethrough. The sense/drive algorithm 10 then proceeds to repeat the decision step 102, at a repetition rate faster than the change in force on the first piezo-electric transducer P1, which will typically occur over several milliseconds. Accordingly, in a digital system, the sensing loop may be repeated, a new sampled sensed voltage VSens obtained along with a new interim digital representation and a new total sensed voltage VSensT, every 100 μs to 1 ms to get a good sensing performance in a Human-Machine Interface.

When the answer to decision step 102 is NO for all parasitic paths or at least the one or more tested parasitic paths, e.g. with the lowest magnitude or highest value turn on voltage Vto, the reconstructed or total accumulated sensed voltage VsensT is computed by the controller 50 during a determination step 103 as the sum of the accumulated voltage Vacc(i−1) and the current voltage segment, i.e. (Vout−Vref) of the sensed voltage VSens The value of the total accumulated sensed voltage VsensT represents the voltage that would be at output voltage Vout at the output node 13, if no parasitic path exist in the driver stage 4.

A specific example of the sense/drive algorithm 10 comprise a sensing loop, wherein the piezo-electric transducer P1 continues to sense a force application, until decision step 104 determines whether the total accumulated sensed voltage VSensT is greater than the activation level Vact or the host device sends an external prompt, which will result in the controller 50 activating the driver stage 4, step 107, e.g. bias driver stage switches Q1 and Q2, to generate and transmit the driver voltage signal VDR to the piezo-electric transducer P1. At the end of the voltage waveform applied on the piezo-electric transducer P1, e.g. a single cycle of a sine waveform with a frequency of 200 Hz and 50V amplitude, then the piezo-electric transducer system 1 returns to the sensing loop. One of the driver stage switches, e.g. Q1 and Q2 or QDR1 and QDR2, or the sensing switches QS may turn on long enough to discharge the piezo-electric transducer P1, e.g. to 0 V, at step 109, and then the driver stage switches, e.g. the first and second switches Q1 and Q2, may be turned off to enable electrical charge generated by the piezo-electric transducer P1 to accumulate, and thereby make the voltage between the output voltage Vout and the reference voltage Vref increase and/or decrease with force applications on the piezo-electric transducer P1, as step 110.

When the original force application continues, e.g. during the release of the force, or during a second consecutive force application, the controller 50 determines if the output voltage Vout, i.e. the output voltage Vout minus the reference voltage Vref, representative of the sensed voltage VSens, is approaching the parasitic leakage condition in step 102. In other words whether the output voltage Vout is a large enough negative voltage to overcome the leakage or turn-on voltage Vto of the body diode in one of the driver stage switches, e.g. the second switch Q2, by determining if the output voltage Vout is greater than a predetermined threshold voltage Vth of at least one of the driver stage switches, e.g. the second switch Q2, which is less (or greater) than the leakage voltage Vto. If the sensed voltage VSens and therefore the output voltage Vout reaches the threshold voltage Vth, e.g. −0.5V, then (step 105) the controller 50 adds the voltage segment of the output voltage Vout between 0 and approximately the threshold voltage Vth typically, just above the threshold voltage Vth, to an accumulated voltage Vacc in step 105. The sensing switch QS, e.g. the third switch Q3, is turned on (step 106) by the controller 50 for a length of time, which is long enough to discharge the first piezo-electric transducer P1 to 0V. The accumulation process may be repeated (step 105) at a rate faster than the change in force on the first piezo-electric transducer P1, which will typically occur over several milliseconds, e.g. every 1000 samples per second (1 kS/s) to 10000 samples per second (10 kS/s). During each sample, if the threshold voltage Vth is not met, then the total sensed voltage VSensT may be calculated (step 103) by the controller 50 to be the previous accumulated voltage Vacc(i−1) plus the current reference voltage segment value VSens, i.e. Vout minus the reference voltage Vref, which may be 0 (for ground).

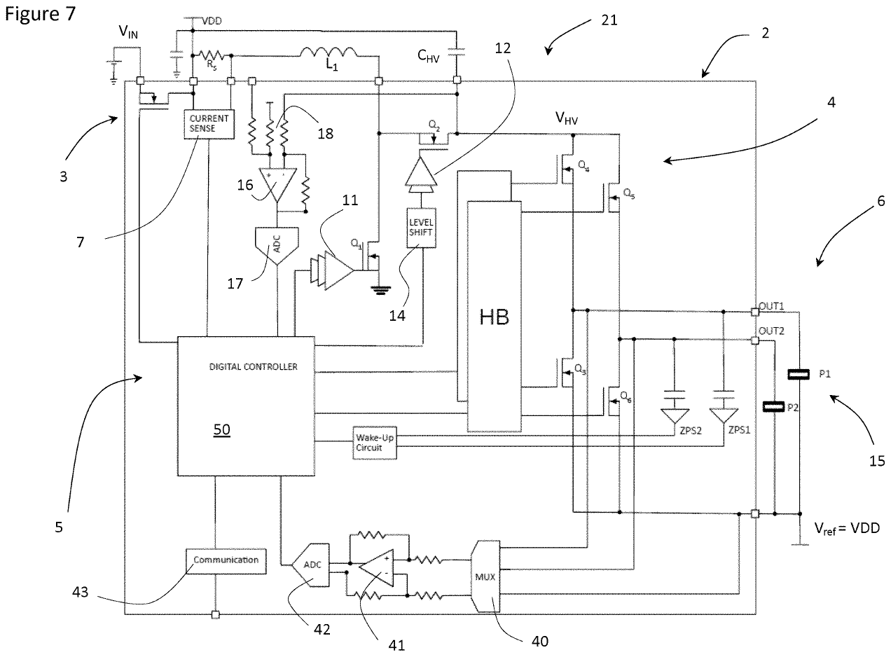

With reference to FIG. 7, a single driver circuit may be utilized to independently drive multiple loads 15, each comprising a plurality of piezo-electric transducers, e.g. P1 and P2 in the illustrated embodiment. A multi-piezo-electric transducer system 21, includes the piezo-electric transducer circuit 2 comprising the input stage 3, the driver stage 4, which may include a power converter circuit, the amplifier bias/switch control 5, and the output stage 6. The piezo-electric transducer system 21 may be implemented in a single chip or using discrete parts due to the high power to process. The input stage 3 may be connected to a voltage source, such as a battery, typically generating an input voltage Vin of between 2 V and 10 V, preferably 3.6 V to 5V. The driver stage 4, as described hereinbefore may be a forward-boost/reverse-buck converter that generates a clean sine waveform, as described herein before. The driver stage 4 may include the inductor L1 connected to the voltage source VIN, and the one or more driver stage switches, e.g. the first low side switch Q1 connected between the inductor L1 and ground, and the second switch Q2 connected between the inductor L1 and the output stage 6. The control terminal, e.g. gate, of the transistor in the first switch Q1 may be connected to the first gate driver 11, and the control terminal, e.g. gate, of the transistor in the second switch Q2 may be connected to the second gate driver 12. Both the first gate driver 11 and the second gate driver 12 may be connected to the controller 50, which sends control signals to the first and second gate drivers 11 and 12 to control operation of the driver stage switches, e.g. the first and second switches Q1 and Q2, respectively, as described hereinbefore.

The input stage 3 may include the filter capacitor (CHV) connected across the low voltage source VIN and the high voltage waveform VHV, and the sense resistor (RS) connected between the low voltage source VIN and the single inductor L1. The single inductor L1 may be connected between the sense resistor RS and a switching node SW of the power converter circuit of the driver stage 4. As above, the current sensor 7 may be connected on both sides of the sense resistor RS and to the controller 50 for measuring the current, and/or the voltage entering the inductor L1 and the power converter circuit of the driver stage 4.

The one or more driver stage switches may include a fourth (or first piezo-selecting) switch Q4 connected between the second switch Q2 and the first piezo-electric transducer P1, which may be activated by the controller 50 to independently control the charging/discharging of the first piezo-electric transducer P1, and a fifth (or second piezo-selecting) switch Q5 connected between the second switch Q2 and the second piezo-electric transducer P2, which may be activated by the controller 50 to independently control the charging/discharging of the first and second piezo-electric transducers P1 and P2, respectively, during haptic drive thereof. Zero power wake-up sensing mechanisms ZPS1 and ZPS2, as disclosed in U.S. Pat. No. 11,302,859 filed Sep. 20, 2018 in the name of Boreas Technologies, Inc., which is incorporated herein by reference, may be provided to wake up the piezo-electric transducer system 21, in particular the first piezo-electric transducer P1 or the second piezo-electric transducer P2, based on a force applied to, and resulting voltage signals received from, the first piezo-electric transducer P1 or the second piezo-electric transducer P2.

The sensed voltage signals VSens1 or VSens2 generated by the first and/or second piezo-electric transducers P1 and P2, respectively, may often exceed the turn on voltage levels Vto of the body diodes of the driver stage switches, e.g. Q1, Q2, Q4 and Q5, or the sensing switches, e.g. QS, Q3 or Q6. Because of the parasitic paths via the driver stage switches, e.g. the fourth switch Q4 and the fifth switch Q5 and/or the sensing switches Q3 and Q6, a voltage difference between the two ends of each piezo-electric transducer P1 and P2 will develop when a change in force occurs thereon. When the output voltage Vout1 or Vout2 representing the sensing voltage VSens1 or VSens2 goes above the leakage or turn on voltage of the parasitic diodes of one or more of the driver stage switches or sensing switches, current will start to flow in the diodes of the driver stage switches and/or the sensing switches QS which will limit the output voltage signal Vout available to the controller 50 based on the sensed voltage VSens1 or VSens2 from the piezo-electric transducers P1 or P2 to measure the change of force applied thereto. For example, anytime the output voltage (or the sensed voltage VSens1 or VSens2): (Vout1 or Vout2)−VHV>Vto (~0.3V), e.g. for driver stage switches Q4 and Q5, OR (Vout1 or Vout2)−Vref<Vto (~−0.3V), e.g. for sensing switches Q3 and Q6, there may be a triggering of a parasitic path. There are numerous situations when this may happen, e.g. the driver stage 4 may be driving 0 V across the second piezo-electric transducer P2 while the first piezo-electric transducer P1 is sensing a force application creating the first sensing voltage signal VSens1 higher than 0.3V, which would trigger the parasitic path in the driver stage switch Q4.

FIG. 8 illustrates the issue using the simple case of FIG. 7. When a change of force on the first piezo-electric transducer P1 generates a first sensed voltage VSens1 across the piezo-electric transducer P1 with an amplitude that is high enough to trigger one of the two parasitic diodes in one of the driver stage switches, e.g. Q4 or Q5, then the first output voltage Vout1 based on the first sensing voltage VSens1 across the first piezo-electric transducer P1 saturates near the turn on voltage Vto of one of the driver stage switches instead of being proportional to the force applied on the first piezo-electric transducer P1. In simple terms, once the parasitic diodes of one of the driver stage switches saturates the first output voltage Vout1 based on the first sensing voltage VSens1, the first piezo-electric transducer P1 becomes insensitive to further change in force in the same direction.

For example, with reference to FIG. 8, for a conventional multi-piezo system, during an initial force application on the first piezo-electric transducer P1, a positive sensed voltage VSens1 will develop on the first piezo-electric transducer P1 between OUT1 and Vref. Assuming the driver stage 4 doesn't drive any signal, the sense voltage VSens1 will develop normally in response to a force application, as in FIG. 5. However, if it happens that a second drive voltage signal VDR2 is applied on the second piezo-electric transducer P2 at the same time, the first sensing voltage signal VSens1 on the first piezo-electric transducer P1 will saturate at various voltages based on the second driver voltage signal VDR2, e.g. at high voltage node VHV, on the second piezo-electric transducer P2 because of the body diode in one or more of the driver stage switches, e.g. Q4. Consequently, it is not possible to read a force applied accurately on the first piezo-electric transducer P1 or the second piezo-electric transducer P2 in this multi-channel architecture when a driver voltage signal, e.g. VDR1 or VDR2, is being sent to either of the first and second piezo-electric transducers P1 and P2 via high-voltage node VHV.

The sensing switches may comprise the third switch Q3, which may be connected between the first piezo-electric transducer P1 and a reference voltage Vref, with the control terminal, e.g. gate, connected to the controller 50, and a sixth switch Q6, which may be connected between the second piezo-electric transducer P2 and the reference voltage Vref, with the gate connected to the controller 50, provide similar functionality as the third switch Q3 in FIG. 3, i.e. enable the controller 50 to independently control the discharge of the first piezo-electric transducer P1 and the second piezo-electric transducer P2 independently of each other in all situations. Accordingly, the third and sixth switches Q3 and Q6 may be activated by the controller 50 to zero the first or second output voltages Vout1 or Vout2, respectively, based on the first or second sensed voltages VSens1 or VSens2 across the first piezo-electric transducer P1 or the second piezo-electric transducer P2, respectively, each time the first or second output voltage Vout1 or Vout2 approaches the turn-on voltages, e.g. 0.3 V, of the body diodes of the driver stage switches or sensing switches, e.g. Q4, Q5, Q3 or Q6, i.e. each time the output voltage Vout1 or Vout2 reaches a threshold voltage Vth1 or Vth2, e.g. +/−0.25 V, which is less than the turn-on voltage Vto of the body diode (or greater than for negative turn on voltages or has an absolute value less than the turn-on voltage) of one or more of the driver stage switches and/or sensing switches, e.g. Q4, Q5, Q3 or Q6. A different first threshold voltage Vth1 may be set for each driver stage switch, e.g. Q4 and Q5, and a different second threshold voltage Vth2 for each sensing switch Q3 and Q6, or a single threshold voltage Vth1 may be set for some or all of the piezo-selecting switches and for some or all of the sensing switches.

Typically, when sensing on the first piezo-electric transducer P1, while another action is taking place, e.g. driving the second piezo-electric transducer P2 or continued sensing on the first or second piezo-electric transducer P1 or P2, a first (upper) threshold voltage Vto1 (about 0.2V to 0.4V) is set for the driver stage switch Q4 based on the second driver voltage signal VDR2 at node VHV causing a parasitic trigger, and a second (lower) threshold voltage Vto2 (−0.2V to −0.4V) is set for the sensing switch Q3 based on the output voltage Vout based on sensing voltage VSens2 causing a parasitic trigger. The same is true for the second piezo-electric transducer P2, i.e. (Vout)−VHV>Vto1 (~0.3V), e.g. for switches Q4 and Q5 or (Vout)−Vref<Vto2 (~−0.3V), e.g. for switches Q3 and Q6.

The algorithm 10 executed by the controller 50 may digitally reconstruct the real accumulated sensing voltage VSensT1 or VSensT2 across the first piezo-electric transducer P1 and/or the second piezo-electric transducer P2 by adding up the different segments of the output voltage Vout moving between 0 and the appropriate threshold voltage Vth1 or Vth2, e.g. absolute value less than (or prior to reaching) the turn-on voltage Vto of the body diode of the one or more of the corresponding driver stage switches, e.g. Q1 and Q2 or QDR1 and QDR2, or corresponding sensing switches, e.g. Q4, Q5, Q3 or Q6 thus providing much better sensing performance for sensing voltages VSens1 and VSens2 across the first and second piezo-electric transducers P1 and P2, which corresponds typically to a release in a touch interface or simultaneous or coincidental driving and/or sensing of the first and second piezo-electric transducers P1 and P2.

To enable independent accurate sensing on all channels, e.g. the first and second piezo-electric transducers P1 and P2, independently of drive activity on other channels zeroing or sensing switches Q3 and Q6 may be activated Accordingly, when a force is applied to the first piezo-electric transducer P1, while a driver voltage signal VDR2 is applied to the second piezo-electric transducer P2, (See left side of FIG. 8) the third switch Q3 is used to discharge the first piezo-electric transducer P1 when the output voltage signal Vout1 based on the first sensing voltage VSens1 of the first piezo-electric transducer P1 reaches either of the threshold voltages Vto1 or Vto2, e.g. +/−0.25V, near (less than) the leakage or turn on voltage Vto1 or Vto2, e.g. +/−0.3V, at which the body diode of the fourth switch Q4 or the third switch Q3, respectively, would start to pass current. The controller 50 may digitally determine the first total accumulated sensing voltage signal VSensT1 of the first piezo-electric transducer P1 from the small segments between 0 V and the corresponding threshold voltages Vth1 and Vth2, e.g. one negative and one positive, to provide an accurate representation of the real total sensing voltage signal VSensT1 from the first piezo-electric transducer P1, as above with reference to FIGS. 1 and 2.

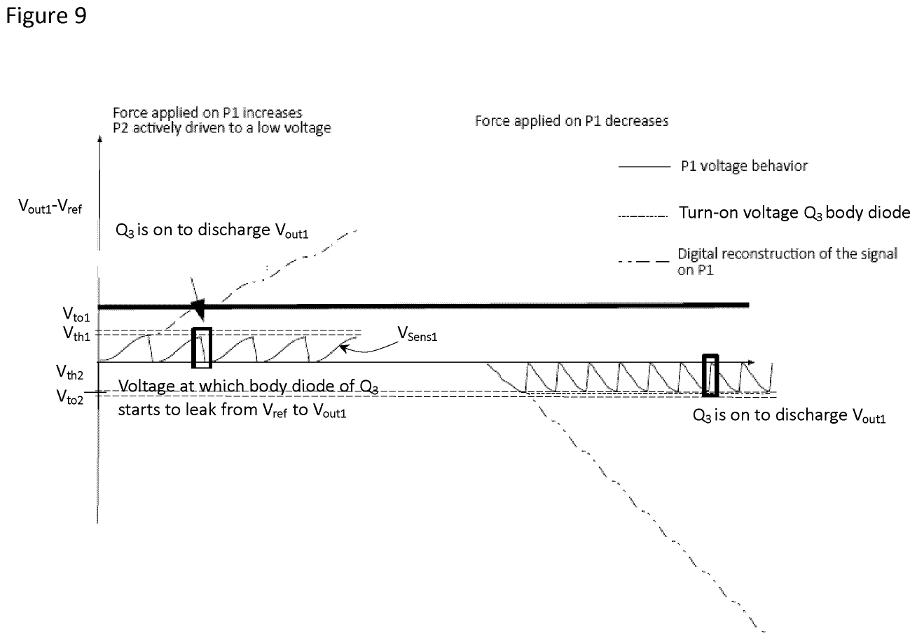

FIG. 9 presents the result of the method described in FIG. 6. When in sensing mode, the controller 50 monitors the sensed voltage signals VSens1 and VSens2, i.e. the output voltage Vout1 and Vout2, across the first and second piezo-electric transducers P1 and P2, respectively, continuously for an analogue implementation or at a rate that is faster compared to the measured signal for a digital implementation. In the case of a human-machine interface, the change in force will typically occur over several milliseconds, consequently a sample rate between 1 kS/s and 10 kS/s is sufficient to get a good representation of the sensed voltage signals VSens1 and VSens2.

With reference to the left side of FIG. 9, when the second piezo-electric transducer P2 is actively driven by the controller 50, and simultaneously a force is applied to the first piezo-electric transducer P1, whereby the sensed voltage signal VSens1 on the first piezo-electric transducer P1 approaches the turn on or leakage voltage of one of the parasitic diodes in the driver stage switches, e.g. Q1 and Q2 or QDR1 and QDR2, or sensing switches QS, e.g. the third switch Q3 or the fourth switch Q4, and becomes greater than or equal to the first threshold voltage Vth, the third switch Q3 is turned on to discharge the first output voltage Vout1 corresponding to the first sensing voltage VSens1 of the first piezo-electric transducer P1 to Vref, e.g. VDD. The length of time the third switch Q3 is on will depend on several factors, such as the capacitance of the first piezo-electric transducer P1, the conduction channel resistance Rdson of the third switch Q3 and the presence of the filter 8. The third switch Q3 should be on long enough to substantially discharge the first piezo-electric transducer P1 from the threshold voltage to 0 V. The time may be between 100 uS and 1 ms for an exemplary embodiment. Just before turning the third switch Q3 on, the first output voltage Vout1 is measured and added as the current sensed voltage VSens to an accumulator in or connected to the controller 50 to add each voltage segment into the accumulator voltage Vacc. The accumulator enables the controller 50 to keep track of the actual first and second sensing voltages VSens1 and VSens2 that would have appeared on the piezo-electric transducer P1 or P2 if no parasitic path existed in the switches, e.g. transistors, of the driver stage 4.

For the same situation, i.e. while a driver voltage signal VDR2 is applied to the second piezo-electric transducer P2, when the force is released from the first piezo-electric transducer P1, the same problem arises as detailed above with reference to FIGS. 4 and 5.

Accordingly, the third switch Q3 may be activated by the controller 50 to zero the first sensed voltage signal VSens1 or the first output voltage Vout1 measured across the first piezo-electric transducer P1 each time the first output voltage Vout1 approaches the turn-on voltages Vto1, e.g. 0.3 V, of the body diodes of, e.g. the fourth switch Q4 and/or the turn-on voltage Vto2 of the third switch Q3, i.e. each time the first output voltage Vout1 reaches the threshold voltages Vth1 and/or Vth2, e.g. +/−0.25 V, less than the turn-on voltages Vto1 or Vto2. The algorithm 10 executed by the controller 50 may digitally reconstruct the real total sensing voltage VSensT1 across the first piezo-electric transducer P1 by adding up a current sensed voltage VSens, i.e. an interim digital representation thereof, and the accumulated voltage Vacc from the different segments (See right side of FIG. 8) of the output voltage Vout1 representing the sensed voltage signal VSens moving between 0 and just above the corresponding threshold voltages Vto1 or Vto2, i.e. less than the turn-on voltage of the body diode of the third and fourth switches Q3 and Q4, thus providing much better sensing performance for negative voltages across the first piezo-electric transducer P1.

A voltage multiplexer 40 may be connected between the sensing switches, e.g. the third and sixth switches Q3 and Q6, and the controller 50. The voltage multiplexer 40 may provide two functions: 1) multiplex the output voltage signals, e.g. Vout1 and Vout2, from different channels, e.g. the first piezo-electric transducer P1 and the second piezo-electric transducer P2, to an amplifier 41 optimized for a small input range, e.g. 100 uV to 100 mV/bit, that provides very accurate reading of the output voltages, e.g. Vout1 to Voutn, from the plurality of piezo-electric transducers, e.g. P1 to Pn, and enables high sensitivity; and 2) provide a high voltage input device to also protect the low voltage electronics from the high-voltage actuator signal, e.g. 50V, on the plurality of piezo-electric transducers P1 to Pn, when they are driven. An analog to digital converter (ADC) 42 may be provided for converting the voltage segments of the output voltages Vout1 to Voutn, i.e. the sensed voltage signals VSens, to digital representations. A communication module 43 may also be provided for communication between the controller 50 and the external device, e.g. mobile device, such as the external prompts, as herein before described.

The method of limiting the voltage (positive and negative) below a threshold voltage Vth, at which point current starts to leak in the body diodes of switches, e.g. transistors, connected to the piezo-electric transducers, e.g. P1 and/or P2, e.g. the driver stage switches (transistors), e.g. Q1 and Q2 or QDR1 and QDR2, or sensing switches, such as the third, fourth, fifth and sixth switches Q3, Q4, Q5 and Q6. Using the sensing switches, e.g. the third and sixth switch Q3 and Q6, enables the sensing voltages, e.g. VSens1 to VSensn, from multiple piezo-electric transducers to be read accurately and independently, while sharing the same power transistors for the driver function of the IC. The digital algorithm 10 in the controller 50 enables the sensing voltage signals, e.g. VSens1 and Vsens2, from the first and/or second piezo-electric transducers P1 and P2 to be digitally reconstructed accurately as if no parasitic path existed. Based on that reconstructed signal, the piezo-electric transducer system 1 may be used to accurately use multiple piezo-electric transducers as sensors and play haptic waveforms on them.

The sensing algorithm provided in the controller 50 shows the following characteristics: 1) provides accurate sensing of an increase and decrease of pressure on the piezo-electric transducers P1 and P2; 2) compatible with multi-channel architecture; 3) may only require a single transistor, e.g. Qs, Q3 or Q6, per sensing channel; 4) enables driving a haptic response on one channel, e.g. piezo-electric transducer P1, while sensing a force application on a different channel, e.g. the second piezo-electric transducer P2; 5) ability to sense positive and negative voltages across multiple piezo transducers; 6) avoids cross-talk or coupling effect when sensing multiple transducers; 7) direct sensing of low voltage signal at the high voltage nodes enable high sensitivity; 8) configurable “reset” threshold to adapt the method to real parasitic path present in the system; and 9) may not need extra components for sensing than for driving.

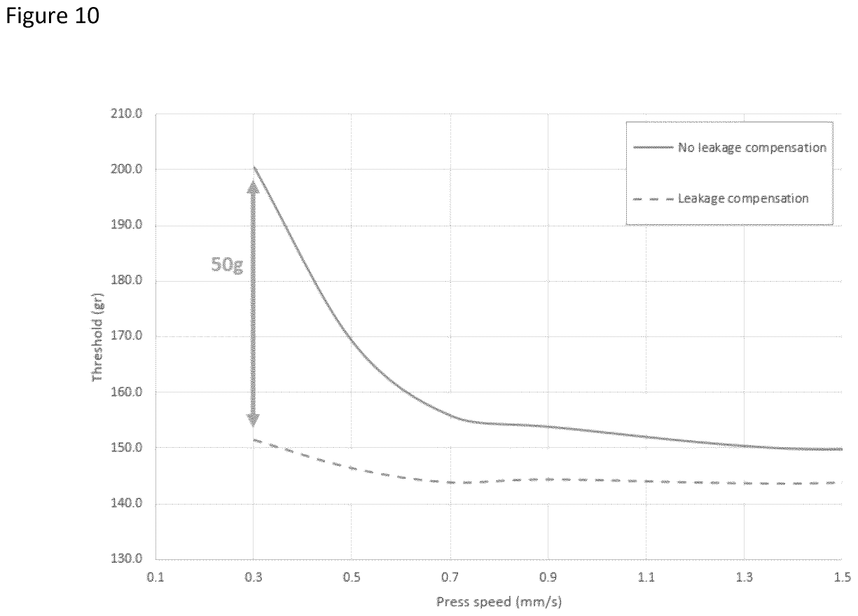

Another enhancement that may be applied to any piezo-electric transducer system including the aforementioned piezo-electric transducer systems 1 and 21 is a leakage compensation system. The leakage compensation system may be an algorithm and can be implemented as hardware directly into an IC chip, e.g. a piezo-electric transducer driver chip, or in computer software instructions stored on memory executed by a control processor used in combination with the piezo-electric transducer driver chip. With reference to FIG. 10, the X axis represents the press speed of the application of a force on a surface of the piezoelectric transducer P1 or P2. The Y axis is the force threshold at which the piezoelectric transducer P1 or P2 triggers a haptic response. Ideally, the force threshold is insensitive, i.e. a flat line response, to the press speed. Unfortunately, as illustrated by the solid line, because of the leakage effect, when the press speed lowers, the effective force threshold required to trigger a haptic response increases. However, if a leakage compensation algorithm of the leakage compensation system is applied, the effective threshold, as illustrated by the dashed line, may be made much more stable at any press speed.

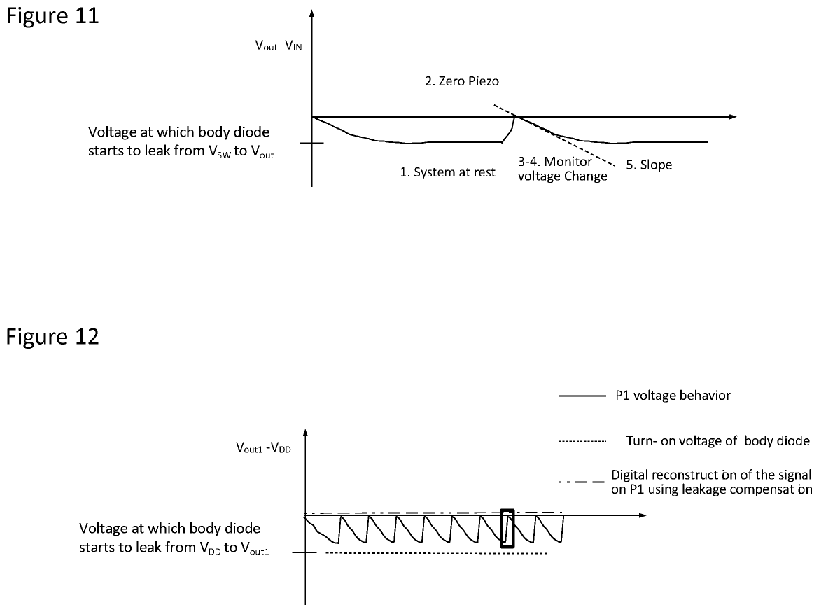

A first step in a method of reducing the effect of electric charge leakage is to obtain a charge leakage characteristic, e.g. a charge leakage slope in voltage over time (mV/ms) or amps (mA), of the piezo-electric transducer P1 and/or P2. If the leakage characteristic is not already known or provided a test may be performed. The test to determine the charge leakage characteristic may be performed initially upon manufacture and stored in memory for future use. The charge leakage characteristic may be actively adjusted by the controller 50 over time and for different operating conditions, but because of operating conditions, e.g. operating temperature and circuit age, the test may be performed by the controller 50 each time the piezo-electric transducer system 1 is turned on and/or periodically while the piezo-electric transducer system 1 is operating. With reference to FIG. 11, an example of a test may include one or more of the following steps:
Step 1: Confirm that the piezo-electric transducer system 1 is at a rest state, i.e. no change of force is occurring on the piezo-electric transducer P1 and/or P2. The rest state may include a stable non-zero output voltage (Vout−Vin) reading of between +1 V to −1V, typically about −300 mV. The confirmation can be done by monitoring the electrical signal across the piezo-electric transducer P1, e.g. VSens or Vout, to make sure the electrical signal is stable. The resting voltage may be the voltage at which the body diode of one of the switches, e.g. Q2, starts to leak from the switching node voltage VSW to the output voltage Vout
Step 2: Excite the piezo-electric transducer system 1 electrically, e.g. by shorting the piezo-electric transducer P1 and/or P2, or forcing a certain voltage on the piezo-electric transducer P1 and/or P2 which zeros the output voltage (Vout−Vin).
Step 3: Reconfigure the piezo-electric transducer system 1, i.e. electrically, to be back into an active sensing arrangement.
Step 4: Monitor the change in voltage happening over time across the piezo-electric transducer P1 and/or P2 until the voltage signal, e.g. VSens or Vout, reaches the rest state again.
Step 5: Calculate the charge leakage characteristic, e.g. the charge leakage slope, from the data in Step 4. The charge leakage slope can be expressed in different units, e.g. Amps, but volts over time (mV/ms) is used in this description.

At this point the charge leakage characteristic is stored in memory, and there are a plurality of configurations in which to use the charge leakage characteristic information.

A first configuration may completely cancel the charge leakage effect by providing a hardware integration in the piezo-electric transducer system 1, as described above. In a first embodiment, the controller 50 is configured to:
1. Zero the output voltage Vout across the piezo-electric transducer P1, e.g. by shorting the piezo-electric transducer P1, before reaching the threshold voltage, i.e. the rest state, e.g. −300 mV, generating voltage segments, as hereinbefore described with reference to FIG. 5.
2. Let the piezo-electric transducer P1 discharge toward the normal rest state. Referring to FIG. 12, if no signal is applied on the piezo-electric transducer P1, the actual voltage will have a similar shape as the negative sawtooth shown, but with a lesser slope.
3. Repeat 1 and 2 continuously. The timing of 1 may need to be adjusted, e.g. accelerated, based on the sense/drive algorithm 10 when a voltage signal is present on the piezo-electric transducer P1.

While steps 1-3 are repeated, the data, i.e. digital representations of the voltage segments, generated by the controller 50 for each time the voltage approaches the turn-on voltage Vto or reaches or surpasses the threshold voltage Vth, is processed to be corrected by the charge leakage characteristic, e.g. the charge leakage slope, that characterizes the piezo-electric system 1. For instance, a digital controller 50 processes the data so that the negative sawtooth seen in FIG. 12 looks like a flat line. For example, the digital controller 50 may simply add a set value based on the charge leakage characteristic to each digital representation of each voltage segment or to a sum of a plurality of digital representations of a plurality of voltage segments based on the charge leakage characteristic. For a given leakage slope, a predetermined adjustment value may be added to each digital representation of each voltage segment or the sum of a plurality of digital representations of a plurality of voltage segments to generate an adjusted voltage value, i.e. an adjusted force value. When a signal, e.g. force, is applied, the same correction is applied which make sure the signal, e.g. haptic response or electronic response, communicated to the user represent the actual force applied. Combining that with the sense/drive algorithm 10 provides a system that can even measure DC force signal.

With reference to FIG. 12, in the square box, the piezo-electric transducer P1 and/or P2 is zeroed at a threshold voltage Vth before, e.g. greater than a negative threshold voltage Vth or less than a positive threshold voltage Vthe, the output voltage (Vout1−VDD) arrives at the rest position, e.g. the leakage point of the body diode of Q2. When applying the leakage compensation, the resulting digital signal forms a flat line since the analog voltage, only changes at the pace set by the leakage which is compensated.

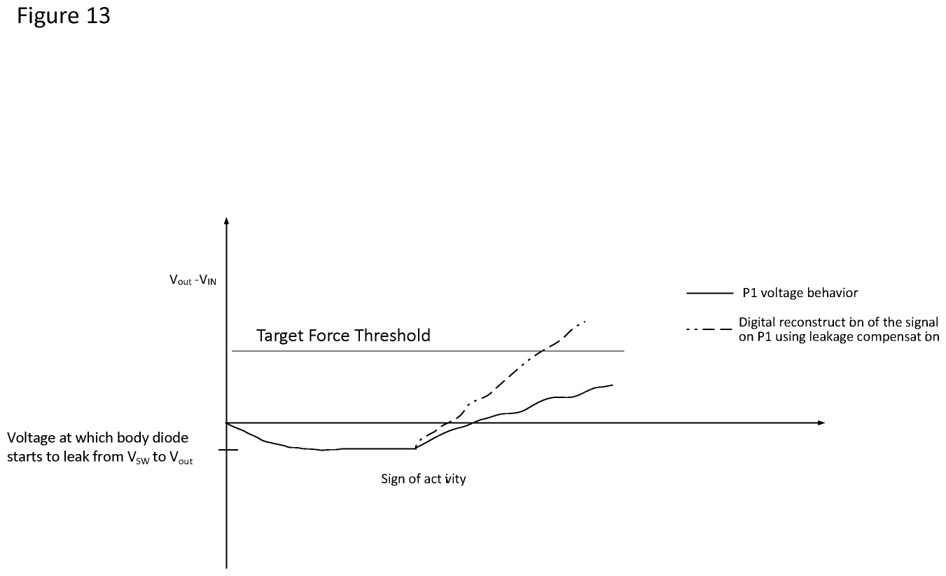

With reference to FIG. 13, in an alternative embodiment, which can be implemented in hardware or software stored in non-transitory memory and executed by the controller 50, for implementing the same concept in a piezo-electric transducer system that cannot automatically zero the piezo-electric transducer P1 and/or P2 repeatedly. The leakage compensation system having already determined the charge leakage characteristic, begins monitoring the piezo-electric system 1 at the rest state where the voltage across the piezo-electric transducer P1 or P2 sits normally at some nominal value, e.g. −300 mV, dashed line in FIG. 12.
1. The leakage compensation system, e.g., the controller 50, monitors the voltage at the piezo-electric transducer P1 and/or P2 for any sign of activity, i.e. voltage change from force application;
2. As soon as a weak starting voltage signal, e.g. above 100 mV, preferably above 50 mV from the rest voltage, is detected on the piezo-electric transducer P1 and/or P2, the leakage compensation system starts to compensate the digital representations of the voltage signal read using the leakage characteristic, e.g. leakage slope of the system to generate an adjusted voltage value.
3. The corrected signal, i.e. the digital representation of the adjusted voltage value, is continuously or repeatedly, e.g. every 1 ms sampling rate, compared to the target force threshold, which when reached or exceeded results in the controller 50 activating of a haptic response, i.e. activation of the driver stage 4 to send a driver voltage signal across the piezo-electric transducer P1 or P2. A different rate of sampling may be used use based on the system requirements.

The correction may be stopped if the raw analogue voltage goes back to the resting voltage, since the leakage detection system may not be able to differentiate between no signal and a very slow signal.

For the second system and method, instead of correcting the raw data and comparing to the target force threshold, the target force threshold may be corrected in time based on the leakage characteristic and compared to the uncorrected voltage value, e.g. the digital representation of the measured output voltage.

The controller 50 for controlling the piezo-electric transducer circuit 2, for example, a digital controller, may be a computer. The controller 50 may contain a processor, a storage device, a memory having software stored therein that defines the abovementioned functionality, input and output (I/O) devices (or peripherals), and a local bus, or local interface allowing for communication within the controller 50. The local interface may be, for example but not limited to, one or more buses or other wired or wireless connections, as is known in the art. The local interface may have additional elements, which are omitted for simplicity, such as controllers, buffers (caches), drivers, repeaters, and receivers, to enable communications. Further, the local interface may include address, control, and/or data connections to enable appropriate communications among the aforementioned components.

The processor may be a hardware device for executing software, particularly that stored in the memory. The processor may be any custom made or commercially available single core or multi-core processor, a central processing unit (CPU), an auxiliary processor among several processors associated with the present controller 50, a semiconductor based microprocessor, e.g. in the form of a microchip or chip set, a macro-processor, or generally any device for executing software instructions.

The memory may include any one or combination of volatile memory elements, e.g. random access memory (RAM, such as DRAM, SRAM, SDRAM, etc.)) and non-volatile memory elements, e.g., ROM, hard drive, tape, CDROM, etc. Moreover, the memory may incorporate electronic, magnetic, optical, and/or other types of storage media. Note that the memory may have a distributed architecture, where various components are situated remotely from one another, but may be accessed by the processor.

The software may define functionality performed by the controller 50, in accordance with the present invention. The software in the memory may include one or more separate programs, each of which contains an ordered listing of executable instructions for implementing logical functions of the controller 50, as described below. The memory may contain an operating system (O/S). The operating system essentially controls the execution of programs within the controller 50 and provides scheduling, input-output control, file and data management, memory management, and communication control and related services.

The I/O devices may include input devices, for example but not limited to, a keyboard, mouse, scanner, microphone, etc. Furthermore, the I/O devices may also include output devices, for example but not limited to, a printer, display, etc. Finally, the I/O devices may further include devices that communicate via both inputs and outputs, for instance but not limited to, a modulator/demodulator (modem; for accessing another device, system, or network), a radio frequency (RF) or other transceiver, a telephonic interface, a bridge, a router, or other device.

When the controller 50 is in operation, the processor may be configured to execute the software stored within the memory, to communicate data to and from the memory, and to generally control operations of the controller pursuant to the software, as explained above.

When the functionality of the controller 50 is in operation, the processor may be configured to execute the software stored within the memory, to communicate data to and from the memory, and to generally control operations of the controller pursuant to the software. The operating system may be read by the processor, perhaps buffered within the processor, and then executed.

When the controller 50 is implemented in software, it should be noted that instructions for implementing the controller 50 may be stored on any computer-readable medium for use by or in connection with any computer-related device, system, or method. Such a computer-readable medium may, in some embodiments, correspond to either or both the memory or the storage device. In the context of this document, a computer-readable medium is an electronic, magnetic, optical, or other physical device or means that may contain or store a computer program for use by or in connection with a computer-related device, system, or method. Instructions for implementing the system may be embodied in any computer-readable medium for use by or in connection with the processor or other such instruction execution system, apparatus, or device. Although the processor has been mentioned by way of example, such instruction execution system, apparatus, or device may, in some embodiments, be any computer-based system, processor-containing system, or other system that can fetch the instructions from the instruction execution system, apparatus, or device and execute the instructions. In the context of this document, a “computer-readable medium” may be any means that can store, communicate, propagate, or transport the program for use by or in connection with the processor or other such instruction execution system, apparatus, or device.

Such a computer-readable medium may be, for example but not limited to, an electronic, magnetic, optical, electromagnetic, infrared, or semiconductor system, apparatus, device, or propagation medium. More specific examples, i.e. a non-exhaustive list, of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

In an alternative embodiment, where the controller 50 is implemented in hardware, the controller 50 may be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

We claim:

1. A method of operating a piezo-electric driver circuit, the method comprising:
obtaining a leakage characteristic of the piezo-electric driver circuit;
repeatedly sensing a first sensed voltage generated by a first force applied to a first piezo-electric transducer;
zeroing the first sensed voltage each time the first sensed voltage reaches a threshold voltage, thereby generating a plurality of first voltage segments;
generating a digital representation of each of the plurality of first voltage segments;
generating adjusted digital representations based on the leakage characteristic;
updating a first accumulation sum with each adjusted digital representation; and
determining a first total sensed voltage across the first piezo-electric transducer from the first accumulation sum.

2. The method according to claim 1, wherein the threshold voltage is based on a first trigger level of a first parasitic conduction path of a first switch in the piezo-electric driver circuit.

3. The method according to claim 1, wherein the leakage characteristic comprises an amount of leakage voltage over time.

4. The method according to claim 1, wherein determining the first total sensed voltage further includes:
generating an interim digital representation of each first sensed voltage, each time the first sensed voltage is sensed;
adjusting the interim digital representation of each first sensed voltage based on the leakage characteristic; and
determining the first total sensed voltage across the first piezo-electric transducer from the first accumulation sum and the interim digital representation.

5. The method according to claim 2, wherein the first switch in the piezo-electric driver circuit comprises a driver circuit switch including the first parasitic conduction path, wherein the method comprises transmitting a driver voltage signal to the first piezo-electric transducer for generating a force or displacement response on the first piezo-electric transducer.

6. The method according to claim 5, further comprising:
generating an interim digital representation of each first sensed voltage, each time the first sensed voltage is sensed; and
wherein the step of transmitting the driver voltage signal includes transmitting the driver voltage signal when the first total-sensed voltage plus the interim digital representation is greater than a predetermined activation level.

7. The method according to claim 2, wherein the first threshold voltage is greater than a negative first turn-on voltage of the first parasitic conduction path.

8. The method according to claim 2, wherein the first threshold voltage is less than a positive first turn-on voltage of the first parasitic conduction path.

9. An apparatus for operating a first piezo-electric transducer, configured for coupling to a voltage source, which provides an input voltage, and configured to transmit a driver voltage signal across the first piezo-electric transducer, the apparatus comprising:
a driver circuit, comprising a first driver circuit switch including a first parasitic conduction path, configured to be connected to the first piezo-electric transducer, the driver circuit configured to receive the input voltage and transmit the driver voltage signal for generating a force response or a displacement response on the first piezo-electric transducer;
a sensing circuit configured to sense a first sensed voltage generated by a first force applied to the first piezo-electric transducer, the sensing circuit including a first sensing switch; and
a controller configured to:
control the first driver switch and the first sensing switch,
obtain a leakage characteristic of the driver circuit;
repeatedly sense the first sensed voltage generated by the first force applied to a first piezo-electric transducer;
zero the first sensed voltage each time the first sensed voltage reaches a threshold voltage, thereby generating a plurality of first voltage segments;
generate a digital representation of each of the plurality of first voltage segments;
generate adjusted digital representations based on the leakage characteristic;
update a first accumulation sum with the adjusted digital representations; and
determine a first total sensed voltage across the first piezo-electric transducer from the first accumulation sum.

10. The apparatus according to claim 9, wherein the threshold voltage is based on a first trigger level of the first parasitic conduction path.

11. The apparatus according to claim 10, wherein the controller is also configured to:
generate an interim digital representation of the first sensed voltage, each time the first sensed voltage is sensed;
adjust the interim digital representation of one or more of the first sensed voltage based on the leakage characteristic; and
determine the first total sensed voltage across the first piezo-electric transducer from the first accumulation sum and the interim digital representation.

12. The apparatus according to claim 9, wherein the controller is also configured to:
generate an interim digital representation of the first sensed voltage, each time the first sensed voltage is sensed;
adjust the interim digital representation of each of the first sensed voltage based on the leakage characteristic; and
determine the first total sensed voltage across the first piezo-electric transducer from the first accumulation sum and the interim digital representation.

13. The apparatus according to claim 9, wherein the controller is also configured to:
generate an interim digital representation of the first sensed voltage, each time the first sensed voltage is sensed;
adjust the interim digital representation of one or more of the first sensed voltage based on the leakage characteristic; and
transmit the driver voltage signal when the first total sensed voltage, comprising the first accumulation sum plus the interim digital representation, is greater than a predetermined activation level.

14. The apparatus according to claim 10, wherein the threshold voltage is greater than a negative turn-on voltage of the first parasitic conduction path.

15. A method of operating a piezo-electric transducer with a piezo-electric driver circuit, including a first switch with a first parasitic conduction path, the method comprising:
determining a charge leakage characteristic of the piezo-electric driver circuit;
repeatedly sensing a first sensed voltage generated by a first force applied to the piezo-electric transducer;
generating a digital representation of the first sensed voltage;
generating an adjusted digital representation of the first sensed voltage based on the leakage characteristic; and
transmitting a driver voltage signal to the first piezo-electric transducer for generating a force response or a displacement response on the first piezo-electric transducer when the adjusted digital representation of the first sensed voltage reaches a target force threshold voltage.

16. The method according to claim 15, wherein the threshold voltage is based on a first trigger level of the first parasitic conduction path.

17. The method according to claim 15, wherein the leakage characteristic comprises an amount of leakage voltage over time.

18. An apparatus for operating a first piezo-electric transducer, configured for coupling to a voltage source, which provides an input voltage, and configured to transmit a drive voltage across the first piezo-electric transducer, the apparatus comprising:
a driver circuit, comprising a first driver circuit switch including a first parasitic conduction path, configured to be connected to the first piezo-electric transducer, the driver circuit configured to receive the input voltage and transmit the drive voltage for generating a force or displacement response on the first piezo-electric transducer;
a sensing circuit configured to sense a first sensed voltage generated by a first force applied to the first piezo-electric transducer, the sensing circuit including a first sensing switch; and
a controller configured for:
determining a charge leakage characteristic of the driver circuit;
repeatedly sensing the first sensed voltage generated by the first force applied to the piezo-electric transducer;
generating a digital representation of the first sensed voltage;
generating an adjusted digital representation of the first sensed voltage based on the leakage characteristic; and
transmitting a drive voltage to the first piezo-electric transducer for generating a force response or displacement response on the first piezo-electric transducer when the adjusted digital representation of the first sensed voltage reaches a target force threshold voltage.

19. The apparatus according to claim 18, wherein the threshold voltage is based on a first trigger level of the first parasitic conduction path.

20. The apparatus according to claim 18, wherein the leakage characteristic comprises an amount of leakage voltage over time.
